(19) United States
(12) Patent Application Publication
(10) Pub. No.: US 2025/0079054 A1
(43) Pub. Date: Mar. 6, 2025

(54) MAGNET WIRE WITH LOW-PERMITTIVITY INSULATION

(71) Applicant: ESSEX SOLUTIONS USA LLC, Atlanta, GA (US)

(72) Inventors: Shengqing Xu, Fort Wayne, IN (US); Matthew E. Leach, Fort Wayne, IN (US); Zhiyang Zhao, Fort Wayne, IN (US)

(21) Appl. No.: 18/923,092

(22) Filed: Oct. 22, 2024

Related U.S. Application Data
(60) Provisional application No. 63/535,305, filed on Aug. 29, 2023.

(51) Int. Cl. H01F 5/06

(52) U.S. Cl. CPC H01F 5/06

(57) ABSTRACT

Magnet wire with low-permittivity insulation includes a conductor and at least one insulation layer formed around the conductor. The insulation layer includes a base polymeric material, and one or more additives incorporated into the base polymeric material. The one or more additives include at least one of (i) a polycyclic aromatic hydrocarbon or (ii) a partially or fully hydrogenated compound of a polycyclic aromatic hydrocarbon. Additionally, the one or more additives lower the permittivity of the insulation layer relative to a control insulation layer formed solely from the base polymeric material.

### CROSS-REFERENCE TO RELATED APPLICATION

This application claims priority to U.S. Provisional Application No. 63/545,305, filed Oct. 23, 2023 and entitled “Magnet Wire with Low-Permittivity Insulation,” the contents of which is incorporated by reference herein in its entirety.

### TECHNICAL FIELD

Embodiments of the disclosure relate generally to magnet wire and, more particularly, to magnet wire including insulation formed with one or more additives that lower permittivity and enhance performance.

### BACKGROUND

Magnet wire, also referred to as winding wire or magnetic winding wire, is utilized in a wide variety of electric machines and devices, such as inverter drive motors, motor starter generators, transformers, etc. Typically, magnet wire is constructed by applying electrical insulation to a metallic conductor, such as a copper, aluminum or alloy conductor. The insulation provides for electrical integrity and prevents shorts in the magnet wire. Certain magnet wire includes enamel insulation applied in successive layers and cured in an oven. Enamel layers are typically applied as a varnish containing thermosetting polymeric material suspended in solvent, and the heat curing removes substantially all of the solvent and leaves a solid polymeric layer. Other magnet wire includes thermoplastic polymeric insulation that is melt extruded onto a conductor. Yet other magnet wire includes a combination of thermoset and thermoplastic insulation.

Regardless of the type of insulation system (e.g., thermoset enamel, thermoplastic, etc.) used on a magnet wire, it is desirable to improve or enhance the electrical performance of the insulation. For example, ever increasing customer requirements and desires for certain magnet wire applications, such as hybrid electric vehicle (“HEV”) and/or automotive applications, make it desirable to improve the electrical performance of magnet wire insulation. It is often desirable to enhance the dielectric properties and/or partial discharge inception voltage (“PDIV”) of a magnet wire. The PDIV of a magnet wire generally refers to a voltage at which localized insulation breakdowns can occur. Partial discharge typically begins with voids, cracks, or inclusions within an insulation layer; however, it can also occur along surfaces of an insulation material. Once begun, partial discharge progressively deteriorates an insulation material and ultimately leads to electrical breakdown. In general, lower permittivity insulation materials have higher PDIV values.

Accordingly, there is an opportunity for improved magnet wire including low-permittivity insulation that enhances electrical performance. In particular, there is an opportunity for improved magnet wire having insulation formed with one or more additives that lower insulation permittivity while improving the partial discharge inception voltage and/or dielectric properties of the magnet wire.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items; however, various embodiments may utilize elements and/or components other than those illustrated in the figures. Additionally, the drawings are provided to illustrate example embodiments described herein and are not intended to limit the scope of the disclosure.

FIGS. 1A-1D are cross-sectional views of example magnet wire constructions that include low-permittivity insulation, according to illustrative embodiments of the disclosure.

FIGS. 2A-2B are schematic illustrations of insulation layers in which additives have been incorporated to lower insulation permittivity, according to an illustrative embodiment of the disclosure.

### DETAILED DESCRIPTION

Various embodiments of the present disclosure are directed to magnet wire that includes a conductor and low-permittivity insulation formed around the conductor. A wide variety of different types of insulation may be formed around the conductor including, but not limited to, thermosetting or thermoset enamel insulation, thermoplastic insulation, or a combination of thermosetting and thermoplastic insulation. Additionally, at least one layer of insulation may incorporate or be formed with one or more additives that function to lower the permittivity of the insulation. As a result, the electrical performance of the insulation, such as the partial discharge inception voltage (“PDIV”) and/or dielectric characteristics, may be enhanced.

As desired in various embodiments, a wide variety of different additives and/or combinations of additives may be incorporated into one or more insulation layers and/or used in the formation of one or more insulation layers (i.e., incorporated into materials used to form insulation layers) to lower the permittivity of the insulation layer. In certain embodiments, one or more additives may be incorporated (e.g., blended into, laminated onto, coated, on, etc.) into a single insulation layer (e.g., a thermosetting layer, a thermoplastic layer, etc.), such as a base layer formed around the conductor, a midcoat layer, a topcoat, layer, or any other suitable insulation layer. In other embodiments, one or more additives may be incorporated into a plurality of insulation layers.

In certain embodiments, the additives utilized to lower insulation permittivity may include one or more polycyclic aromatic hydrocarbons (“PAHs”) and/or one or more partially or fully hydrogenated compounds of polycyclic aromatic hydrocarbons. In certain embodiments, PAHs and/or partially or fully hydrogenated compounds of PAHs include, but are not limited to, polyphenyls (as defined below), polybenzyls (as defined below). A few non-limiting examples of suitable additives include, but are not limited to, fluorene, anthracene, triphenylene, tetracene, pentacene, phenanthrene, phenalene, phenylene, biphenylene, chrysene, pyrene, perylene, corannulene, coronene, ovalene, pentalene, indene, azulene, heptalene, indacene, acenaphthylene, fluoranthene, accanthrylene, napthacene, pleuadene, picene, pentaphene, tetraphenylene, hexacene, hexaphene, rubicene, coronene, trinaphthylene, pyranthrene, heptaphene, heptacene, and their derivatives, and/or their partially or fully hydrogenated compounds. In certain embodiments, the additives may include, but are not limited to, Dibenzyltoluene (“DBT”) (CAS No: 26898-17-9); Monobenzyl toluene (“MBT”) (CAS No: 27776-01-8); Therminol® 75 manufactured and sold by Eastman Chemical Company and including as components Terphenyl (CAS No. 26140-60-3), Phenanthrene (CAS No. 85-01-8), and Quaterphenyl (CAS No. 29036-02-0); or Therminol® 66 manufactured and sold by Eastman Chemical Company and including as components Terphenyl, hydrogenated (CAS No. 61788-32-7), Quaterphenyls and higher polyphenyls, partially hydrogenated (CAS No. 68956-74-1), and Terphenyl (CAS No. 26140-60-3). A wide variety of other suitable additives may be utilized in addition to those set forth in the non-limiting examples, such as any suitable aryl components having a lower dielectric constant than that of the base material used to form the insulation layer.

For purposes of this disclosure, the term “polyphenyl” shall mean a polycyclic aromatic hydrocarbon that includes at least one phenyl group, such as, biphenyl, triphenyl, tetraphenyl, etc. In other words, the “poly” in polyphenyl may represent bi(2), tri(3), tetra(quarter,4), hexaphenyl (6), octaphenyl(8) or higher. Examples of polyphenyls include, but are not limited to, 4-benzylbiphenyl (CAS No. 613-42-3); terphenyl (CAS No. 26140-60-3), p-terphenyl (CAS No. 92-94-4), m-terphenyl (CAS No. 92-06-8), o-terphenyl (CAS No. 9984-15-1); 1,2,3-triphenylbenzene (CAS No. 1165-14-6), 1,2,4-triphenylbenzene (CAS No. 1165-53-3), 1,3,5-triphenylbenzene (CAS No. 612-71-5); triphenylmethane (CAS No. 519-73-3), (triphenylmethyl)benzene (CAS No. 630-76-2), 1,1,1-triphenylethane (CAS No. 5271-39-6), 1,1,2-triphenylethane (CAS No. 1520-42-9), 1,1,3-triphenylpropane (CAS No. 19120-39-9); triphenylene (CAS No. 217-59-4); p-tetraphenyl (CAS No. 135-70-6), m-tetraphenyl (CAS No. 1166-18-3), tetraphenylmethane (CAS No. 630-76-2); p-pentaphenyl (CAS No. 3073-05-0), pentaphenylbenzene (CAS No. 18631-82-8), 1,2,3,4,5-pentaphenyl-1,3-cyclopentadiene (CAS No. 2519-10-0).

For purposes of this disclosure, the term “polybenzyl” shall mean a polycyclic aromatic hydrocarbon that includes at least one benzyl group, such as, bibenzyl, tribenzyl, tetrabenzyl, etc. In other words, the “poly” in polybenzyl may represent bi(2), tri(3), tetra(quarter,4), or higher. Examples of polybenzyls include, but are not limited to, bibenzyl (CAS No. 103-29-7), (E)-stilbene (CAS No. 103-30-0), (Z)-stilbene (CAS No. 645-49-8); 1,2-dibenzylbenzene (CAS No. 792-68-7), 1,3-dibenzylbenzene (CAS No. 15180-20-8), 1,4-dibenzylbenzene (CAS No. 793-23-7); dibenzyltoluene (CAS No. 26898-17-9), 2,3-dibenzyltolune (CAS No. 115643-65-7), 2,4-dibenzyltolune (CAS No. 94871-33-7); tribenzylmethane (CAS No. 4742 May 5), 1,2,3-tribenzylbenzene (CAS No. 143319-04-4), 1,2,4-tribenzylbenzene (CAS No. 96068-48-3); 1,2,4,5-tetrabenzylbenzene (CAS No. 1460-03-3); tetrabenzylethylene (CAS No. 19754-02-0)

In certain embodiments, a single additive for lowering permittivity may be utilized. In other embodiments, a combination of additives or a mixture or blend of multiple additives may be utilized. In the event that a combination of additives is incorporated, any suitable blending ratio of additives may be utilized. Further, one or more additives may be selected based upon a wide variety of suitable characteristics as desired in various embodiments. For example, in certain embodiments, at least one additive may have a boiling point at standard atmospheric pressure (760 mmHg) that is greater than a desired value, such as 280° C. As another example, in certain embodiments, at least one additive may have a dielectric constant at 20-150° C. that is less than a desired value, such as 3.2.

Additionally, any suitable loading factors of additives may be utilized as desired. In other words, any suitable weight percentage of additives may be incorporated into a material used to form an insulation layer. In certain embodiments, an additive (or a combination of additives) may constitute between approximately 1.0 percent (1.0%) and approximately sixty percent (60.0%) by weight of a material used to form an insulation layer. For example, in various embodiments, the additives may constitute approximately 0.1, 0.5, 1.0, 3.0, 5.0, 7.0, 10.0, 15.0, 20.0, 25.0, 30.0 35.0 40.0, 45.0, 50.0, 55.0, or 60.0 percent by weight of a material used to form an insulation layer, a weight percentage included in a range between any two of the above values, or a weight percentage included in a range bounded on the maximum end by one of the above values. A higher loading factor of an additive may generally lead to a lower permittivity in the resulting insulation layer.

As a result of incorporating one or more additives into the material(s) utilized to form one or more layers of magnet wire insulation, the permittivity of the insulation layer(s) may be lowered or reduced. In certain embodiments, one or more additives may be incompatible with the base insulation material prior to curing the insulation such that the additive(s) do not chemically compound with the base insulation material. In other words, the additive may be dispersed within the base insulation material prior to curing. Following curing of the insulation material, at least a portion of the additive(s) may remain within the finished insulation layer. Given the lower permittivity of the additive(s) relative to the base insulation material, the additive(s) present within the insulation layer assist in lowering the permittivity of the insulation layer. In certain embodiments, a portion of the additive(s) may be evaporated or burned off, thereby resulting in the formation of voids within the cured insulation layer. For example, the insulation layer may resemble a foamed or porous layer given the voids created by the evaporated additive. The voids may result in the insulation layer have a lower permittivity relative to an insulation layer formed without the incorporation of one or more additives.

In certain embodiments, the permittivity of an insulation layer formed with one or more additive for lowering permittivity may be at least 0.3 lower than an insulation layer formed without utilizing one or more additives as described herein (i.e., an insulation layer formed using the same base polymeric material without additives). In various embodiments, the permittivity may be at least 0.3, 0.5, 0.7, 0.9, or a greater amount lower. Additionally, the lower permittivity may facilitate the insulation layer having improved electrical properties. For example, the PDIV and/or the dielectric strength of the insulation layer may be enhanced relative to an insulation layer formed without the additive(s). In certain embodiments, the PDIV at 25° C. of an insulation layer formed with one or more permittivity reducing additives may be at least 5.0% higher than an insulation layer formed solely from base insulation material. In various embodiments, the PDIV at 25° C. of an insulation layer formed with one or more additives may be 5.0%, 10.0%, 15.0%, 20.0% or a greater percentage higher than an insulation layer formed without additives.

Embodiments of the disclosure now will be described more fully hereinafter with reference to the accompanying drawings, in which certain embodiments of the disclosure are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

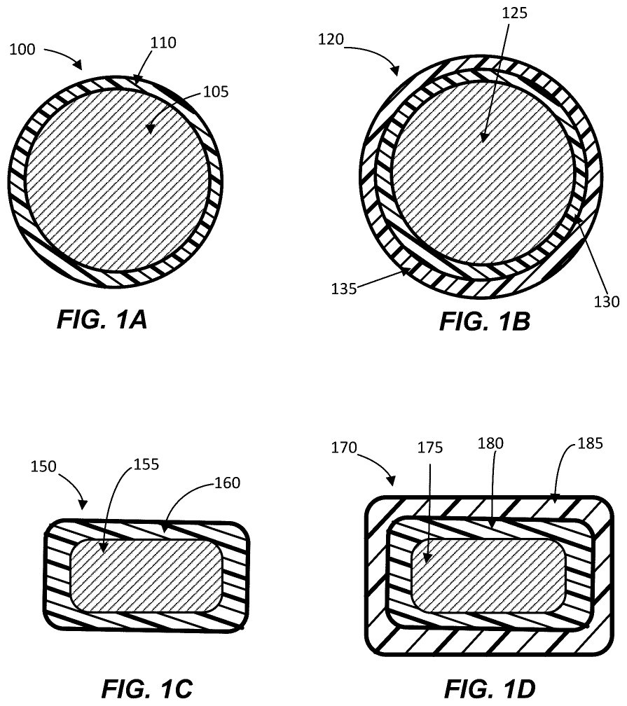

FIGS. 1A-1D illustrate cross-sectional views of example magnet wire constructions that include low-permittivity insulation. In particular, FIG. 1A illustrates a cross-sectional view of an example magnet wire having a round or circular cross-sectional shape in which a single layer of insulation 110 (which may include sublayers) is formed around a conductor 105. FIG. 1B illustrates another example magnet wire 120 having a round cross-sectional shape. The magnet wire 120 may include a conductor 125 and multiple layers 130, 135 of insulation formed around the conductor 125. In other words, the magnet wire 120 may include a basecoat insulation layer 130 formed around the conductor 125, and at least one additional layer of insulation (e.g., topcoat layer 135) formed around the basecoat 130. Although a single additional layer of insulation 135 is illustrated in FIG. 1B, any suitable number of insulation layers may be formed around a basecoat layer 130. For example, a magnet wire 120 may include a basecoat insulation layer, a midcoat insulation layer, and a topcoat insulation layer. In other embodiments, more than three insulation layers may be formed around a magnet wire.

FIG. 1C illustrates an example magnet wire 150 having a rectangular cross-sectional shape in which a single layer of insulation 160 (which may include sublayers) is formed around a conductor 155. FIG. 1D illustrates another example magnet wire 170 having a rectangular cross-sectional shape. Similar to the magnet wire 120 of FIG. 1B, the magnet wire 170 of FIG. 1D may include a conductor 175 and first and second layers 180, 185 of insulation formed around the conductor 175. In other words, the magnet wire 170 may include a basecoat insulation layer 180 formed around the conductor 175, and at least one additional layer of insulation (e.g., topcoat layer 185) formed around the basecoat 180. Any number of additional layers of insulation may be utilized as desired. For example, a magnet wire 170 may include a basecoat insulation layer, a midcoat insulation layer, and a topcoat insulation layer. In other embodiments, more than three insulation layers may be formed around a magnet wire.

The insulation of the example magnet wire constructions 100, 120, 150, 170 illustrated in FIGS. 1A-1D may be formed from a wide variety of suitable materials and/or combinations of materials. For example, insulation layers may be formed from thermosetting polymeric materials, thermoplastic polymeric materials and/or other suitable materials (e.g., semi-conductive materials, inorganic materials including ceramics, glass, etc.) Indeed, as described in greater detail below, magnet wire may be formed with a wide variety of suitable insulation systems. According to an aspect of the disclosure, at least one of the insulation layers is formed utilizing one or more additives that function to lower or reduce the permittivity of the insulation layer.

Each of the layers or components of the magnet wire 170 of FIG. 1D will now be described in greater detail. The example magnet wires 100, 120, 150 of FIGS. 1A-1C may include layers or components similar to those described with reference to FIG. 1D. Indeed, as desired in various embodiments, a magnet wire may be formed with a wide variety of suitable cross-sectional shapes and insulation configurations provided that at least one layer of insulation includes one or more additives that function to reduce copper ion migration.

With reference to FIG. 1D, the conductor 175 may be formed from a wide variety of suitable materials and/or combinations of materials. For example, the conductor 175 may be formed from copper, annealed copper, oxygen-free copper, silver-plated copper, nickel plated copper, tin plated copper, lead plated copper, molybdenum plated copper, tungsten plated copper, copper clad aluminum (“CCA”), a conductive alloy, a material that is coated with copper, any other suitable electrically conductive material that includes copper, aluminum, or any other suitable conductive material or combination of conductive materials. Additionally, the conductor 175 may be formed with any suitable dimensions and/or cross-sectional shapes. As shown, the conductor 175 may have a rectangular cross-sectional shape. In other embodiments, such as those illustrated in FIGS. 1A and 1C, a conductor may have a circular or round cross-sectional shape. In yet other embodiments, a conductor may be formed with a square shape, an elliptical or oval shape, a hexagonal shape, or any other suitable cross-sectional shape. Additionally, as desired for certain cross-sectional shapes such as the illustrated rectangular shape, a conductor may have corners that are rounded, sharp, smoothed, curved, angled, truncated, or otherwise formed. For example, a shaped rectangular wire may have rounded corners.

The conductor 175 may also be formed with any suitable dimensions, such as any suitable gauge, diameter, height, width, cross-sectional area, etc. As one non-limiting example, the longer sides of a rectangular conductor 175 may be between approximately 0.020 inches (508 μm) and approximately 0.750 inches (19050 μm), and the shorter sides may be between approximately 0.020 inches (508 μm) and approximately 0.400 inches (10160 μm). An example square conductor may have sides between approximately 0.020 inches (508 μm) and approximately 0.500 inches (12700 μm). An example round conductor may have a diameter between approximately 0.010 inches (254 μm) and approximately 0.500 inches (12700 μm). Other suitable dimensions may be utilized as desired.

A wide variety of suitable methods and/or techniques may be utilized to form, produce, or otherwise provide a conductor 175. In certain embodiments, a conductor 175 may be formed by drawing input material (e.g., a larger conductor, rod stock, etc.) through one or more dies in order to reduce the size of the input material to desired dimensions. As desired, one or more flatteners and/or rollers may be used to modify the cross-sectional shape of the input material before and/or after drawing the input material through any of the dies. In certain embodiments, the conductor 175 may be formed in tandem with the application of a portion or all of the insulation system. In other words, conductor formation and application of insulation material may be conducted in tandem. In other embodiments, a conductor 175 with desired dimensions may be preformed or obtained from an external source, and insulation material may then be applied via a subsequent process.

With continued reference to FIG. 1D, a plurality of insulation layers 180, 185 are depicted as being formed around the conductor 175. In other embodiments, as shown in FIGS. 1A and 1C, a single insulation layer (e.g., a single layer of extruded thermoplastic insulation, a solecoat of enamel insulation, etc.). In the event that a plurality of insulation layers 180, 185 are formed around the conductor, any suitable number of insulation layers may be formed. For example, as shown in FIG. 1D, a first basecoat insulation layer 180 and a second topcoat insulation layer 185 may be formed. As another example, three insulation layers may be formed, such as a basecoat, a midcoat, and a topcoat layer. Other embodiments may include more than three layers.

Additionally, each insulation layer 180, 185 may be formed from a wide variety of suitable materials. For example, one or more insulation layers may be formed as enamel layers from thermosetting polymeric materials. As another example, one or more insulation layers may be formed from extruded thermoplastic materials. Additionally, it will be appreciated that a given insulation layer may include one or more sublayers. For example, an enamel layer may be formed with any number of sublayers that are successively formed until a desired build thickness is attained. As another example, a thermoplastic layer may be formed from successively extruded layers. Example thermosetting and thermoplastic insulation layers are described in greater detail below.

In certain embodiments in which the magnet wire 170 includes a plurality of insulation layers 180, 185, each of the layers may be formed from the same polymeric material. In other embodiments, at least two of the insulation layers (e.g., layers 180, 185, etc.) may be formed from different materials or materials having different molecular constructions and/or compositions. For example, two enamel layers may be formed from different thermosetting polymeric materials. As another example, two enamel layers may be formed from the same base polymeric materials; however, the two enamel layers may include different fillers and/or additives. As yet another example, two thermoplastic layers may be formed from different materials and/or different material blends. As another example, a first insulation layer may be formed from a thermosetting polymeric material and a second insulation layer may be formed from a thermoplastic material. A wide variety of suitable fillers and/or additives may be selectively incorporated into any of the insulation layers. Additionally, according to an aspect of the disclosure, additives that reduce or lower permittivity may be utilized in conjunction with any number of insulation layers. For example, additives that lower permittivity may be utilized in the formation of each of the layers or into a subset of the layers.

As set forth above, in certain embodiments, a magnet wire 170 may include one or more enamel layers of insulation formed from thermosetting polymeric material. An enamel layer is typically formed by applying a polymeric varnish to the conductor 175 and then baking the conductor 175 in a suitable enameling oven or furnace. The polymeric varnish typically includes polymeric solids material suspended in one or more solvents, wherein the polymeric solids may be thermosetting and/or thermoplastic and/or their compositions with fillers and additives. Following application of the varnish (on the conductor or an underlying insulation layer), solvent is removed by evaporation, heat, and/or radiation, thereby leaving a solid polymeric enamel layer. As desired, multiple sublayers of enamel may be applied to the conductor 175 to form an enamel insulation layer. For example, a first sublayer of enamel may be applied, and the conductor 175 may be passed through an enameling oven or other suitable curing and/or solidifying device. A second sublayer of enamel may then be applied, and the conductor 175 may make another pass through the curing device (or a separate curing device). This process may be repeated until a desired number of enamel coats have been applied and/or until a desired enamel thickness or build has been achieved. As desired, an enameling oven may be configured to facilitate a wire 170 making multiple passes through the oven. Other curing devices that may be utilized in addition to or as an alternative to enameling ovens include, but are not limited to, infrared light systems, ultraviolet light systems, and/or electron beam systems. Any number of enamel layers may be formed in various embodiments. Additionally, each layer of enamel and/or a total enamel build may have any desired thickness, such as a thickness of approximately 0.0002, 0.0005, 0.007, 0.001, 0.002, 0.003, 0.004, 0.005, 0.006, 0.007, 0.008, 0.009, 0.010, 0.012, 0.015, 0.017, or 0.020 inches, a thickness included in a range between any two of the aforementioned values, or a thickness included in a range bounded on either a minimum or maximum end by one of the aforementioned values.

A wide variety of different types of polymeric materials may be utilized as desired to form an enamel layer. Examples of suitable materials include, but are not limited to, polyimide (“PI”), polyamideimide (“PAI”), amideimide, polyurethane, polyester, THEIC polyester, polyesterimide, polysulfone, polyphenylenesulfone, polysulfide, polyphenylenesulfide, polyetherimide, polyamide, polyamide-ester-imide, polyimidesulfones, polybenzimidazole (“PBI”), poly(oxyphenylene benzimidazole) (“OPBI”), poly(benzimidazole-imide) (“PBII”), polybenzimidzopyrrolone (“PBIP”), polyketones, a phenolics polymer, an epoxide polymer, silicone-containing polyimide, a silicone polymer, fluoride-containing polyimide, a fluorinated polymer, a suitable combination of materials, etc. In certain embodiments, if multiple layers of enamel are formed, each enamel layer may be formed from the same polymeric material or base polymeric material. For example, multiple layers of PI enamel may be formed. As another example, a first enamel layer may include filled PI while a second enamel layer included unfilled PI. In other embodiments, at least two layers of enamel may be formed from or may include different polymeric materials. For example, a first enamel layer may include PI while a second enamel layer includes PAI. It will be appreciated that any suitable enamel layers or combination of enamel layers may be incorporated into a magnet wire insulation system.

As desired, a wide variety of commonly used additives (other than the additives described herein to lower permittivity) may be combined with a polymeric material used to form an enamel layer. Examples of such additives include crosslinkers, curing promoters, heat stabilizers, antioxidants, UV stabilizers, plasticizers, antistatic agents, antiblocking agents, blowing agents, lubricants, process modifiers, and/or processing aids, rheological modifiers (e.g., thinners, thickeners, etc.), defoaming agents (e.g., silicone type, fluorine type, or polymer type defoaming agents, etc.), leveling agents to reduce surface tension, compatibilizers, coupling or surface-treatment agents, adhesion promoters, flame retardants (e.g., phosphorus type flame retardants, nitrogen type flame retardants, metal salt flame retardants, etc.), reinforcement modifiers (e.g., fibers, fillers, minerals, etc.), inorganic non-metallic fillers in spheres, fibers or irregular shapes, organic fillers, pigments, dyes, and/or colorants (e.g., phthalocyanine blue, phthalocyanine green, iodine green, disazo yellow, crystal violet, titanium oxide, carbon black, naphthalene black, etc.), antimicrobial agents, deodorants, and/or water absorbents.

Example crosslinkers include, but are not limited to, isocyanate compound, blocked isocyanate compound, cyanate ester compound, aziridine compound, acid anhydride group-containing compound, carboxyl group-containing compound, carbodiimide group-containing compound, benzoxazine compound, maleimide compound, citraconimide compound, nadimide compound, allylnadimide compound, vinyl ether compound, vinyl benzyl ether resin, thiol compound, melamine compound, guanamine compound, amino resin, phenol resin, alkyd resin, acrylic resin, unsaturated polyester resin, diallyl phthalate resin, silicone resin, xylene resin, furan resin, ketone resin, triallyl cyanurate resin, tris(2-hydroxyethyl) isocyanurate-containing resin, triallyl trimellitate-containing resin, dicyclopentadiene resin and thermosetting resin obtained by trimerization of an aromatic dicyanamide.

Example curing promoters include, but are not limited to, imidazole derivatives, guanamines (e.g., acetoguanamine, benzoguanamine, etc.), polyamines (e.g., diaminodiphenylmethane, m-phenylenediamine, m-xylenediamine, diaminodiphenylsulfone, dicyandiamide, urea, urea derivatives, melamine, polybasic hydrazide, etc.), organic acid salts and/or epoxy adducts thereof, amine complex of boron trifluoride, triazine derivatives (e.g., ethyldiamino-s-triazine, 2,4-diamino-s-triazine, 2,4-diamino-6-xylyl-s-triazine, etc.), tertiary amines (e.g., trimethylamine, triethanolamine, N,N-dimethyloctylamine, N-benzyldimethylamine, pyridine, N-methylmorpholine, hexa (N-methyl) melamine, 2,4,6-tris(dimethylaminophenol), tetramethylguanidine, 1,8-diazabicyclo [5,4,0]-7-undecene (“DBU”), 1,5-diazabicyclo[4,3,0]-5-nonene (“DBN”), etc.), organic acid salts and/or tetraphenyl boroates thereof, polyvinylphenol, polyvinylphenol bromide, organic phosphines (e.g., tributyl phosphine, triphenyl phosphine, tris-2-cyanoethyl phosphine, etc.), and quaternary phosphonium salts (e.g., tri-n-butyl(2,5-dihydroxyphenyl)phosphonium bromide, hexadecyltributyl phosphonium, etc.).

In certain embodiments, one or more other filler materials may be incorporated into an enamel layer as desired. Examples of suitable filler materials include, but are not limited to, inorganic materials such as metals, transition metals, lanthanides, actinides, carbon nanotubes, boron nitride, metal oxides, and/or hydrated oxides of suitable materials such as aluminum, tin, boron, germanium, gallium, lead, silicon, titanium, chromium, zinc, yttrium, vanadium, zirconium, nickel, etc. (e.g., titanium dioxide, silica or silicon dioxide, etc.); suitable organic materials such as polyaniline, polyacetylene, polyphenylene, polypyrrole, other electrically conductive particles; and/or any suitable combination of materials (e.g., a mixture or blend of metal oxides, etc.). In certain embodiments, the filler material(s) may enhance corona resistance and/or one or more thermal properties (e.g., temperature resistance, cut-through resistance, abrasion resistance, heat shock, etc.). The particles of a filler material may have any suitable dimensions, and any suitable blending ratio or fill rate between filler material and polymeric materials may be utilized (e.g., a fill rate of approximately 5, 10, 15, 20, 25, 30, 35, or 40 percent, or a fill rate included in a range between any of these values). Additionally, if a filler includes a blend of different materials, any suitable blending ratio may be utilized between the components of the filler.

In addition to or as an alternative to one or more enamel layers, a magnet wire 170 may be formed with one or more layers of thermoplastic polymeric insulation, such as one or more extruded layers of polymeric insulation. A thermoplastic insulation layer is typically formed by melt extruding a thermoplastic polymeric material around a conductor 175 (and, if present, any underlying insulation layers). Any number of thermoplastic insulation layers may be formed in various embodiments. Additionally, each layer of thermoplastic polymeric insulation may have any desired thickness, such as a thickness between approximately 15 micrometers and approximately 200 micrometers. In various embodiments, a thermoplastic insulation layer may have a thickness of approximately 15, 20, 25, 50, 75, 100, 125, 150, 175, 200, 225, 250, 275, 300, 325, 350, 375, 400, 425, 450, 475, 500, 525, 550, 575, or 600 micrometers, a thickness included in a range between any two of the above values, or a thickness included in a range bounded on either a minimum or maximum end by one of the above values.

A wide variety of suitable materials and/or combinations of materials may be utilized to form extruded thermoplastic insulation. Examples of suitable materials include, but are not limited to, polyetheretherketone (“PEEK”), polyetherketoneketone (“PEKK”), polyetheretherketoneketone (“PEEKK”), polyetherketone (“PEK”), polyaryletherketone (“PAEK”), other suitable polymers that include at least one ketone group and/or their copolymers, polyetherimide (“PEI”) such as Ultem® marketed by Sabic Global Technologies, polyphenylsulfone (“PPSU”) such as Radel® marketed by Solvay Specialty Polymers USA, polyethersulfone (“PESU”), any suitable aromatic polysulfone, polyphenylene sulfide (“PPS”), polybenzimidazole (“PBI”), polycarbonate, one or more polyesters (e.g., polyethylene terephthalate (“PET”), etc.), one or more copolyesters, polyamide, aromatic polyamide, thermoplastic polyimide (“TPI”), one or more acrylic polymer materials, one or more fluoropolymers, polystyrene, and/or various copolymers of multiple materials. In certain embodiments, a thermoplastic insulation layer may be formed from a blend of two or more polymeric materials.

As desired, a wide variety of commonly used additives (other than additives described herein to lower permittivity) may be incorporated into thermoplastic insulation including, but not limited to, crosslinkers, curing promoters, heat stabilizers, antioxidants, UV stabilizers, plasticizers, antistatic agents, antiblocking agents, blowing agents, lubricants, process modifiers and/or processing aids, rheological modifiers (e.g., thinners, thickeners, etc.), leveling agents, compatibilizers, reinforcement modifiers (e.g., fibers, fillers, minerals, etc.), flame retardants, pigments, dyes, colorants, antimicrobial agents, deodorants, and/or water absorbents.

In certain embodiments, one or more other filler materials may be incorporated into a thermoplastic layer as desired. Examples of suitable filler materials include, but are not limited to, inorganic materials such as metals, transition metals, lanthanides, actinides, carbon nanotubes, boron nitride, metal oxides, and/or hydrated oxides of suitable materials such as aluminum, tin, boron, germanium, gallium, lead, silicon, titanium, chromium, zinc, yttrium, vanadium, zirconium, nickel, etc. (e.g., titanium dioxide, silica or silicon dioxide, etc.); suitable organic materials such as polyaniline, polyacetylene, polyphenylene, polypyrrole, other electrically conductive particles; and/or any suitable combination of materials (e.g., a blend of metal oxides, etc.). In certain embodiments, the filler material(s) may enhance corona resistance and/or one or more thermal properties (e.g., temperature resistance, cut-through resistance, heat shock, etc.). The particles of a filler material may have any suitable dimensions, and any suitable blending ratio or fill rate between filler material and polymeric materials may be utilized (e.g., a fill rate of approximately 5, 10, 15, 20, or 25 percent, or a fill rate included in a range between any of these values). Additionally, if a filler includes a blend of different materials, any suitable blending ratio may be utilized between the components of the filler.

In certain embodiments, a plurality of thermoplastic insulation layers may be formed around a conductor 175. In certain embodiments, a plurality of thermoplastic layers may be formed simultaneously via a single co-extrusion process. In other embodiments, a plurality of separate extrusion steps may be utilized to form successive layers. Additionally, in certain embodiments, if multiple layers of thermoplastic insulation are formed, each layer may be formed from the same polymeric material or base polymeric material. For example, multiple layers of PEEK insulation may be formed. As another example, a first PEEK layer may include filled PEEK while a second layer includes unfilled PEEK. In other embodiments, at least two layers of thermoplastic insulation may be formed from or may include different polymeric materials. As a non-limiting example, a first layer may include PPSU while a second layer includes PEEK. It will be appreciated that any suitable thermoplastic layers or combination of thermoplastic layers may be incorporated into a magnet wire insulation system. Additionally, it will be appreciated in certain embodiments that one or more thermoplastic layers may be formed over one or more enamel layers.

In the event that a thermoplastic layer is formed from a polymeric material that is a blend, two or more component polymeric materials may be blended or mixed together at any suitable blend rates or ratios within the blend. For example, each component may constitute between approximately 1.0% and approximately 99% by weight of a polymeric blend. In certain embodiments, each component material incorporated into a blend (e.g., a first component material, a second component material, etc.) may constitute approximately 5, 10, 15, 20, 25, 30, 40, 45, 50, 60, 70, 75, 80, 90, or 95% by weight of the blend, a weight percentage included in a range between any two of the above values (e.g., between approximately 5 and 95%, between approximately 10 and 90%, etc.), or a weight percentage included in a range bounded on either a minimum or maximum end by one of the above values (e.g., at least 5%, at least 10%, no more than 95%, no more than 90%, etc.). Component materials and relative amounts of materials incorporated into a blend may be selected based on a wide variety of suitable factors including, but not limited to, costs of the materials, processing characteristics, desired dielectric breakdown voltage (“DBV”), desired partial discharge inception voltage (“PDIV”), desired cut-through dimension, desired thermal aging properties, desired temperature rating, desired crystallinity, desired flexibility, desired adhesion, etc.

As desired, other types of insulation may be utilized in addition to one or more enamel layers and/or one or more thermoplastic layers. For example, a magnet wire 170 may incorporate one or more suitable wraps or tapes, such as a polymeric tape wrapped around the conductor 175 and any underlying insulation layers. In other embodiments, the insulation system of a magnet wire 170 may include one or more semi-conductive layers of material. A semi-conductive layer may have a conductivity between that of a conductor 175 and that of an insulator, and the use of one or more semi-conductive layers may assist in equalizing or “smoothing out” non-uniform electric, magnetic, and/or electromagnetic fields that may stress the magnet wire insulation.

The insulation materials incorporated into a magnet wire 170 may be selected in order to achieve a wide variety of suitable properties and/or characteristics. For example, polymeric materials and/or various combinations of polymeric materials may be selected in order to achieve a desired thermal classification (or thermal class), thermal index, and/or thermal endurance. Thermal classes, which are generally established by industry standards organizations (e.g., the National Electric Manufacturers Association, the International Electrotechnical Commission, UL, etc.), establish maximum allowable temperatures for an insulation material and/or magnet wire. Example thermal classes include, for example, 150° C., 180° C., 200° C., 220° C., 240° C., 250° C., 260° C., 270° C., and 280° C. A thermal index is generally defined as a number in degrees Celsius that compares the temperature vs. time characteristics of an electrical insulation material. It may be obtained by extrapolating the Arrhenius plot of life versus temperature to a specified time, usually 20,000 hours. As an example of the difference between a thermal class and a thermal index, a material may have a thermal index of 230° C.; however, that material will have a thermal class of 220° C. as it does not meet the requirements of the next available thermal class of 240° C. As another example, polymeric materials may be selected based upon their physical properties (e.g., whether a thermoplastic material is amorphous, crystalline, semi-crystalline, etc.), shrinkage characteristics, resistance to certain fluids (e.g., transmission fluid), partial discharge inception voltage, dielectric strength, and/or any other suitable characteristics.

In certain embodiments, an insulation system formed on a magnet wire 170 may have a wide variety of suitable electrical performance parameters, such as a wide variety of suitable PDIV values and/or dielectric strength or breakdown strength values. In certain embodiments, an insulation system may provide a PDIV value at 25° C. of at least approximately 800, 900, 1000, 1100, 1200, 1250, 1300, 1350, 1400, 1450, 1500, 1550, 1600, 1700, 1800, 1900, 2000, 2100, 2200, 2300, or 2400 volts, or a PDIV value included in a range between any two of the above values. Similarly, in certain embodiments, an insulation system may provide a dielectric strength value (e.g., a dielectric strength value measured by a suitable industry standard test such as a shotbox or foil test, etc.) of at least approximately, 10,000, 11,000, 12,000, 12,500, 13,000, 13,500, 14,000, 14,500, 15,000, 15,500, 16,000, 16,500, 17000, 17,500, 18,000, 18.500, 19,000, 20,000, 20,500, or 21,000 volts, or a dielectric strength value included in a range between any two of the above values. Other suitable performance parameters may be targeted and/or achieved as desired. As described in greater detail below the PDIV values and/or the dielectric strength values of an insulation system may be enhanced as a result of forming insulation layers utilizing one or more additives that lower permittivity.

Additionally, in embodiments that incorporate a plurality of insulation layers, any suitable ratio or ratios of thicknesses may be utilized between the various layers. Using an example of an insulation system having two insulating layers, the first layer may constitute any suitable percentage (e.g., 1-99%, at least 50%, etc.) of the overall thickness of the combined insulation, and the second layer may constitute any suitable percentage of the overall thickness. As desired, thickness ratios of insulating layers may be selected in order to satisfy a wide variety of suitable design parameters. For example, desired electrical performance may be balanced against the cost of materials utilized to form the insulation layers.

Regardless of the insulation system formed on a magnet wire, according to an aspect of the disclosure, one or more additives that lower or reduce permittivity may be utilized in the formation of and/or incorporated into any desired number of insulation layers. For example, one or more additives may be utilized in the formation of a single insulation layer (e.g., layer 180, layer 185, etc.). As other examples, one or more additives may be utilized in the formation of a plurality of insulation layers 180, 185, a subset of insulation layers, or all of the insulation layers.

As desired in various embodiments, a wide variety of different additives and/or combinations of additives may be utilized to reduce or lower permittivity. In certain embodiments, the additives utilized to lower insulation permittivity may include one or more polycyclic aromatic hydrocarbons (“PAHs”) and/or one or more partially or fully hydrogenated compounds of polycyclic aromatic hydrocarbons. In certain embodiments, PAHs and/or partially or fully hydrogenated compounds of PAHs include, but are not limited to, polyphenyls (as defined above), polybenzyls (as defined above). A few non-limiting examples of suitable additives include, but are not limited to, fluorene, anthracene, triphenylene, tetracene, pentacene, phenanthrene, phenalene, phenylene, biphenylene, chrysene, pyrene, perylene, corannulene, coronene, ovalene, pentalene, indene, azulene, heptalene, indacene, acenaphthylene, fluoranthene, accanthrylene, napthacene, pleuadene, picene, pentaphene, tetraphenylene, hexacene, hexaphene, rubicene, coronene, trinaphthylene, pyranthrene, heptaphene, heptacene, and their derivatives, and/or their partially or fully hydrogenated compounds. In certain embodiments, the additives may include, but are not limited to, Dibenzyltoluene (“DBT”) (CAS No: 26898-17-9); Monobenzyl toluene (“MBT”) (CAS No: 27776-01-8); Therminol® 75 manufactured and sold by Eastman Chemical Company and including as components Terphenyl (CAS No. 26140-60-3), Phenanthrene (CAS No. 85-01-8), and Quaterphenyl (CAS No. 29036-02-0); or Therminol® 66 manufactured and sold by Eastman Chemical Company and including as components Terphenyl, hydrogenated (CAS No. 61788-32-7), Quaterphenyls and higher polyphenyls, partially hydrogenated (CAS No. 68956-74-1), and Terphenyl (CAS No. 26140-60-3). A wide variety of other suitable additives may be utilized in addition to those set forth in the non-limiting examples, such as any suitable aryl components having a lower dielectric constant than that of the base material used to form the insulation layer.

In certain embodiments, at least one permittivity lowering additive may have a boiling point at standard atmospheric pressure (760 mmHg) that is greater than 250° C. For example, at least one additive may have a boiling point at standard atmospheric pressure that is greater than 280° C. In certain embodiments, at least one additive may be selected based at least in part upon a curing temperature or a compounding temperature (e.g., an extrusion temperature, etc.) for a polymeric insulation material in which the additive is combined. For example, an additive may be selected for use with a thermosetting polymeric material used to form an enamel layer having a curing temperature that is greater than a boiling temperature of the additive (e.g., a curing temperature of at least 250° C. or at least 280° C.). As another example, an additive may be selected for use with a thermoplastic polymeric material having a compounding temperature that is equal to or greater than the boiling point of the additive. As desired in certain embodiments, at least one additive may have a dielectric constant at 20-150° C. that is less than 3.2.

In certain embodiments, a single permittivity lowering additive may be utilized. In other embodiments, a combination of additives or a mixture or blend of multiple additives may be utilized. For example, any two or more of the additives discussed above or in Appendix A may be blended or mixed together. In the event that a combination of additives is incorporated, any suitable blending ratio of additives may be utilized. For example, each additive may constitute approximately 0.3, 0.5, 1, 5, 10, 15, 20, 25, 30, 40, 50, 60, 70, 75, 80, 90, 95, or 95% of an additive blend, or a percentage included in a range between any two of the above values.

Additionally, any suitable loading factors of additives may be utilized as desired. In other words, any suitable weight percentage of additives may be incorporated into a material (e.g., a polymeric resin used to form an enamel layer, etc.) used to form an insulation layer. In certain embodiments, an additive (or a combination of additives) may constitute between approximately 1.0 percent (1.0%) and approximately sixty percent (60.0%) by weight of a material used to form an insulation layer. For example, the additive(s) may constitute between approximately one percent (1.0%) and approximately twenty percent (20.0%) by weight of a material used to form an insulation layer. In various embodiments, the additive(s) may constitute approximately 0.1, 0.5, 1.0, 3.0, 5.0, 7.0, 10.0, 15.0, 20.0, 25.0, 30.0 35.0 40.0, 45.0, 50.0, 55.0, or 60.0 percent by weight of a material used to form an insulation layer, a weight percentage included in a range between any two of the above values, or a weight percentage included in a range bounded on the maximum end by one of the above values. A higher loading factor of an additive may generally lead to a lower permittivity in the resulting insulation layer.

A wide variety of suitable methods or techniques may be utilized as desired to incorporate one or more additives into an insulation material in order to lower the permittivity of an insulation layer. As one example, for an enamel insulation layer (e.g., an enamel layer formed from a thermosetting polymeric material such as PI or PAI or PBI), one or more additives may be mixed or blended into a varnish or solvent-containing solution that further includes polymeric solids material. The varnish may then be applied onto a magnet wire 170 and subsequently cured. Similarly, one or more additives may be mixed or blended into a paste that is either applied to a magnet wire 170 in a relatively low solvent form and cured or that is subsequently dissolved in a higher solvent-containing solution that may be applied onto a magnet wire and cured. Regardless of how the additive(s) are incorporated into a varnish or paste, the additive(s) may be dispersed within the varnish when it is applied to a magnet wire. When the varnish is cured following application on a magnet wire, the solvent may be evaporated to form a solid enamel layer.

In certain embodiments, following curing, at least a portion of the permittivity lowering additive(s) will remain in the finished insulation layer. The presence of additive(s) within the finished insulation layer having lower permittivity than the base polymeric material will result in a lower permittivity of the insulation layer relative to an insulation layer formed without the additive(s). In certain embodiments, during curing, a portion of the permittivity lowering additives may be evaporated or burned off. For example, evaporation may occur as a result of the curing temperature for the polymeric insulation being greater than the boiling temperature of the additives. As a result, the cured insulation layer may include voids at positions previously occupied by the dispersed additives. In certain embodiments, the cured insulation layer may be characterized as a foamed, partially foamed, or porous layer given the voids. The voids formed within the insulation layer may result in a lower permittivity of the insulation layer relative to an insulation layer formed without the additive(s).

As another example, for an insulation layer formed from a thermoplastic polymeric material (e.g., PEEK, etc.), one or more permittivity lowering additives may be blended into or dispersed within a base polymeric material prior to extrusion. For example, one or more additives may be added, mixed, or blended into a polymeric base material in a suitable thermoplastic compounding device, such as a single screw extruder, a twin screw extruder, or a Brabender mixer. The polymeric material containing the additive(s) may then be extruded onto a magnet wire 170 to form a thermoplastic insulation layer. In certain embodiments, the extrusion temperature or compounding temperature may be higher than the boiling point of the additive(s). However, the positions of the additives within the extruded material may be maintained due to the pressure within the extrusion device. Once applied to a magnet wire and subjected to ambient conditions, in certain embodiments, at least a portion of the additive(s) will remain in the finished insulation layer. The presence of additive(s) within the finished insulation layer will result in a lower permittivity of the insulation layer relative to an insulation layer formed without the additive(s). In certain embodiments, one applied to a magnet wire and subjected to ambient conditions, a portion of the additive(s) may evaporate from the extruded polymeric material, thereby resulting in the formation of voids in the extruded insulation layer. In certain embodiments, the extruded insulation layer may be characterized as a foamed, partially foamed, or porous layer given the voids. The voids formed within the insulation layer may result in a lower permittivity of the insulation layer relative to an insulation layer formed without the additive(s).

In certain embodiments, for both enamel and thermoplastic insulation layers, it will be appreciated that at least a portion of the permittivity lowering additives will remain as residual amounts in a final insulation layer. Any suitable amount of additives may be evaporated and any suitable residual may remain within the finished cured insulation layer. In certain embodiments, the evaporation of desired amounts of additives may be at least partially controlled by one or more processing parameters at which insulation layers are formed and/or cured. In certain embodiments, between approximately six percent (6%) and approximately forty percent (40%) of the permittivity reducing additives incorporated into a material used to form an insulation layer may remain as residual within the finished insulation layer

As a result of incorporating one or more additives into the material(s) utilized to form one or more layers of magnet wire insulation, the permittivity of the insulation layer(s) may be lowered or reduced. For example, the presence of residual additives within a finished insulation layer and/or the voids created in a finished insulation layer may result in lowering the permittivity of the insulation layer relative to a layer that does not include one or more additives or that was not formed without one or more additives. In certain embodiments, the permittivity of an insulation layer formed with one or more permittivity lowering additives at 25° C. and 1 KHz may be at least 0.3 lower than an insulation layer formed without utilizing one or more additives as described herein (i.e., a control polymer or control layer). In various embodiments, the permittivity may be at least 0.3, 0.5, 0.7, 0.9, or a greater amount lower.

Additionally, the lower permittivity may facilitate the insulation layer having improved electrical properties. For example, the partial discharge inception voltage (“PDIV”) and/or the dielectric strength of the insulation layer may be enhanced relative to an insulation layer formed without the additive(s). In certain embodiments, the PDIV at 25° C. of an insulation layer formed with one or more permittivity lowering additives may be at least 5.0% higher than an insulation layer formed solely from base insulation material (i.e., no permittivity lowering additives). In various embodiments, the PDIV at 25° C. of an insulation layer formed with one or more additives may be 5.0%, 10.0%, 15.0%, 20.0% or a greater percentage higher than an insulation layer formed without additives (i.e., a control polymer or control layer).

The magnet wires 100, 120, 150, 170 described above with reference to FIGS. 1A-1D are provided by way of example only. A wide variety of alternatives could be made to the illustrated magnet wires 100, 120, 150, 170 as desired in various embodiments. For example, a different number of insulation layers may be utilized than those that are illustrated. As another example, the cross-sectional shape of a magnet wire and/or one or more insulation layers may be altered. Indeed, the present disclosure envisions a wide variety of suitable magnet wire constructions.

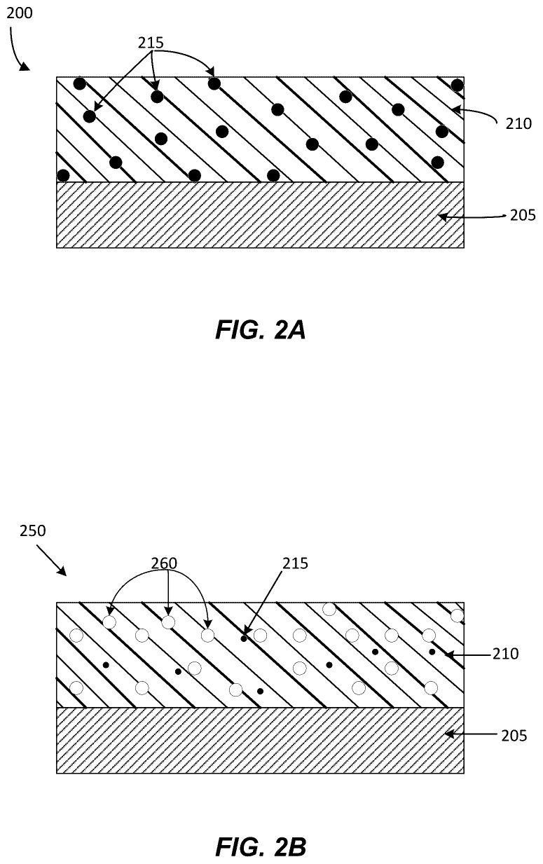

FIGS. 2A-2B depict schematic illustrations 200, 250 of an insulated magnet wire in which additives have been incorporated to lower the permittivity of an insulation layer. The illustrations 200, 250 depict a cross-sectional representation of an example conductor 205 coated with an insulation material that may be utilized for a magnet wire, such as any of the magnet wires 100, 120, 150, 170 depicted in FIGS. 1A-1D. In particular, the illustration 200 of FIG. 2A depicts a conductor 205 following application of an insulation material but prior to curing the insulation material. The illustration 250 of FIG. 2B depicts the conductor 205 subsequent to curing the insulation material to form a solid polymeric insulation layer. Each of these illustrations 200, 250 is described in greater detail below.

Turning first to FIG. 2A, an insulation material 210 may be applied to a conductor, and one or more permittivity lowering additives 215 may be distributed in the applied insulation material 210. As described in greater detail above, a wide variety of different types of insulation materials 210 may be applied to a conductor utilizing any suitable techniques. In certain example embodiments, a varnish containing polymeric material (e.g., thermosetting polymeric material, etc.) and one or more permittivity lowering additives suspended in solvent may be applied to the conductor 205. For example, a varnish containing polyimide (“PI”) and one or more additives may be applied. In other example embodiments, a thermoplastic polymeric material containing one or more additives may be extruded or otherwise applied on the conductor 205. For example, a PEEK material containing one or more additives may be extruded onto the conductor 205. Additionally, any suitable permittivity lowering additives may be incorporated into an insulation material as desired in various embodiments, such as any of the additives discussed above with reference to FIG. 1D.

Turning now to FIG. 2B, following application of the insulation material 210 onto the conductor 205, the insulation material 210 may be cured to form a solid polymeric insulation layer. For example, a varnish may be cured in a suitable enamelling oven or otherwise cured via any other suitable techniques in order to form an enamel layer. During curing, in certain embodiments, a portion of the permittivity reducing additives 215 may be evaporated or burned off. As a result, voids 260 may be formed within the enamel layer. As another example, in certain embodiments, once a thermoplastic polymeric material is extruded onto the conductor 205 and exposed to ambient conditions, a portion of the permittivity reducing additives 215 may evaporate from the extruded insulation layer prior to the layer cooling and/or completely curing. As a result, voids 260 may be formed within the extruded layer. As described in greater detail above, these voids 260 may result in the insulation layer (e.g., enamel layer, extruded layer, etc.) having a lower permittivity relative to layers formed without utilizing the additives described herein. Further, as shown in FIG. 2B, in certain embodiments, at least a portion of the additives 215 may remain in a cured insulation layer as residual additive.

### EXAMPLES

The following examples are intended as illustrative and non-limiting, and represent specific embodiments of the present invention. Wire samples having enamel insulation were prepared with PAI, PI, and PBI enamel. The PAI was prepared by reacting trimellitic anhydride (“TMA”) with methylene diphenyl 4,4′-diisocyanate (“MDI”) in N-methyl-2-pyrrolidone (“NMP”) solvent. Additionally, both of the formulated PAI samples (e.g., the “First PAI” and the “Second PAI”) had a solids content between approximately 36.5% and approximately 40.1% by weight. Both lower solids content PI and high solids content PI samples were formulated by reacting 4,4′-oxydianiline (“ODA”) and pyromellitic dianhydride (“PMDA”) in NMP and/or N—N-dimethylacetamide (“DMAc”) solvents. The lower solids content PI (e.g., the “First PI”) had a solids content of approximately 13.5% by weight, and the high solids content PI samples (e.g., the “Second PI”, the “Third PI”, and the “Fourth PI”) had solids contents between approximately 22.0% and approximately 30.2% by weight. Some samples of PI that were filled with additional filler (e.g., the “Filled PI”) other than the permittivity-reducing additive were also prepared. The PBI (e.g. poly[2,2′-(m-phenylene)-5,5′-bibenzimidazole]) was prepared with a solids content of approximately 26.0% by weight in DMAc and/or NMP solvent from m-phenylenediamine (“MPD”) and 3,3′,4,4′-tetraaminobiphenyl tetrahydrochloride dihydrate (“TABT”). An example PBI is available from PBI Performance Products, Inc. (Charlotte, NC).

Once formulated, magnet wire samples were formed by applying the enamel varnishes to conductors and curing the wire samples. Both control samples and samples in which differing amounts of permittivity lowering or permittivity reducing additives were formed. Unless otherwise stated, the enamel wire samples discussed in the examples were prepared as 18 AWG wire with a “heavy” enamel build. In other words, the wire enamels were applied to an 18 AWG copper wire using multi-pass coating and wiping dies. The “heavy” enamel build has a nominal insulation build of approximately 3.0 mils (76 microns).

A first example illustrated in Table 1 compares the effects of adding dibenzyltoluene (“DBT”) or hydrogenated terphenyl (“HTP”) as permittivity lowering additives to various types of enamel. For these examples, insulation film samples were prepared and measured. Control samples with PI and PAI enamel were compared to samples that include DBT and HTP added to the enamel. Additionally, some comparative examples in which mineral spirits and cyrene were added to enamel were prepared. The relative permittivity & of each sample was measured in a lab under ambient conditions. Permittivity was calculated utilizing Equation 1 below for a parallel plate capacitor:

$$C = ε \frac{A}{d} where ε = {ε}_{0} {ε}_{r} \qquad ( 1 )$$

The thickness “d” of an insulation sample was measured with a Fischer Technology FMP 40 dualscope coating thickness gauge. The diameter of the bottom electrode was 25 mm while the diameter of the top electrode was 15.2 mm. Capacitance was measured at 25° C. with a QuadTech7600 RLC meter using a 2000V alternating current signal at 1 KHz. The permittivity (“k”) was then calculated as the ratio of relative permittivity (Er) to permittivity of a vacuum (co).

TABLE 1
Lowering Permittivity Using a DBT or HTP Additive

| Enamel Film Sample | Permittivity (k) |
|---|---|
| First Polyimide (PI) Control | 3.41 |
| First PI + 2.7% by weight of mineral spirits | 3.64 |
| (for comparison) | |
| First PI + 2.7% by weight of cyrene | 3.49 |
| (for comparison) | |
| First PI + 4.5% by weight of DBT additive | 2.72 |
| Second Polyimide (PI) Control | 3.65 |
| Second PI + 30.0% by weight of DBT additive | 2.38 |
| Third Polyimide (PI) Control | 3.63 |
| Third PI + 18.5% by weight of DBT additive | 2.71 |
| Fourth Polyimide (PI) Control | 3.67 |
| Fourth PI + 25.1% by weight of DBT additive | 2.14 |
| First Polyamideimide (PAI) Control | 4.26 |
| First PAI + 8.0% by weight of mineral spirits | 4.16 |
| (for comparison) | |
| First PAI + 8.0% by weight of cyrene | 4.08 |
| (for comparison) | |
| First PAI + 13.8% by weight of DBT additive | 3.32 |
| Second PAI Control | 4.32 |
| Second PAI + 20.1% by weight of DBT additive | 3.54 |
| Second PAI + 20.1% by weight of HTP additive | 3.79 |
| Filled PI Control | 3.82 |
| Filled PI + 7.0% by weight of DBT | 2.97 |
| Filled PI + 6.6% by weight of mineral spirits | 3.87 |
| (for comparison) | |
| Filled PI + 6.6% by weight of cyrene | 3.79 |
| (for comparison) | |
| Polybenzimidazole (PBI) Control | 4.69 |
| PBI + 20.8% by weight of DBT additive | 3.64 |

As shown in Table 1, the addition of a DBT or HTP additives to various types of enamel coatings resulted in reduced permittivity. For example, the permittivity “k” of the First PI was reduced by approximately 0.7 with a DBT additive, the permittivity of the First PAI was reduced by approximately 0.9 with a DBT additive, and the permittivity of the Filled PI was reduced by approximately 0.85. Other examples also illustrate the lowering of permittivity by incorporating DBT and/or HTP additives. Additionally, the use of a DBT or HTP additive resulted in lower permittivity compared to the addition of mineral spirits (used as a liquid additive to compare to DBT or HTP) to enamel coatings. Indeed, the addition of mineral spirits often increased permittivity.

A second example illustrated in Table 2 evaluates the effects that adding DBT to a PI enamel layer has on the electrical performance of magnet wire. A control wire sample having the First PI enamel was compared to a wire sample prepared with the First PI enamel being applied with a DBT additive. Approximately 4.45% by weight of DBT additive was included in the varnish used to form an enamel layer on a magnet wire. Once the samples were prepared, both the dielectric strength and the PDIV of the samples were measured. Industry standard PDIV tests were performed using a commercially available PDIV testing machine in which a specific ramp of voltages is applied to wire samples at a constant current and an appropriate PDIV value is determined. A root mean square (“RMS”) PDIV is reported for round wire samples, which is lower than a peak PDIV that a wire can withstand. To determine the dielectric breakdown of the round wire samples, a ramped voltage up to 20,000 volts is applied at different temperatures to twisted pairs formed from the wire, and a point of insulation failure or breakdown is identified.

TABLE 2
Electrical Performance as a Result of
Using Permittivity-reducing Additives

| | Control Wire | Wire Sample with |
|---|---|---|
| | Sample | DBT Added to |
| | (First PI) | First PI |
| Solids Content | 13.40% | 13.69% |
| Elongation (%) | 43 | 46 |
| Slit Twist Adhesion | 38 | 42 |
| Thermal Index (° C.) | 231 | 241 |
| Dielectric Breakdown Voltage | 14,676 | 14,718 |
| (Twisted pairs at room | | |
| temperature) | | |
| Dielectric Breakdown Voltage | 9,780 | 13,316 |
| (Twisted pairs at 240° C.) | | |
| PDIV at 25° C. (RMS) | 620 | 750 |
| PDIV at 150° C. (RMS) | 592 | 723 |

As shown in Table 2, the PDIV of a magnet wire may be enhanced as a result of utilizing a DBT additive during the formation of an insulation layer. Additionally, the dielectric strength or dielectric breakdown voltage may be enhanced, especially at higher temperatures. In other words, the electrical performance of the magnet wire may be enhanced as a result of utilizing additives that lower the permittivity of an insulation layer.

A third example illustrated in Table 3 compares the effects of utilizing different permittivity lowering additives during the formation of magnet wire enamel insulation. The utilized polycyclic aromatic hydrocarbon (“PAH”) additives included dibenzyltoluene (“DBT”), Therminol 75, and Therminol 66 (also referred to as “HTP”). Wire samples were prepared utilizing the First PI with varying amounts of additives utilized during the formation of samples. A control sample was also prepared. Each sample was evaluated using the method described above with reference to Table 1 in order to determine the permittivity of the enamel layer.

TABLE 3
Lowering Permittivity Using Different PAH Additivesin PI

| Enamel Film Sample | Permittivity (k) |
|---|---|
| First Polyimide (PI) Control | 3.59 |
| First PI + 3.0% by weight of DBT | 3.36 |
| First PI + 5.0% by weight of DBT | 3.22 |
| First PI + 7.0% by weight of DBT | 3.05 |
| First PI + 7.5% by weight of DBT | 2.98 |
| First PI + 8.0% by weight of DBT | 2.88 |
| First PI + 8.0% by weight of Therminol 75 | 3.24 |
| First PI + 10.0% by weight of Therminol 75 | 2.88 |
| First PI + 8.0% by weight of Therminol 66 | 2.71 |
| First PI + 10.0% by weight of Therminol 66 | 2.64 |

As shown in Table 3, the addition of each of the additives resulted in reduced permittivity. Therminol 66 (“HTP”) appeared to have the best performance and result in the greatest reduction in permittivity. It can be concluded that the permittivity of enamel magnet wire and/or other types of magnet wire insulation may be reduced as a result of utilizing PAH permittivity lowering additives (e.g., polyphenyls, polybenzyls, etc, and/or their fully or partially hydrogenated compounds. Additionally, the use of higher weight percentages of additives may generally result in lower permittivity.

The following examples are intended as illustrative and non-limiting, and represent specific embodiments of the present invention. Samples of extruded thermoplastic insulation were prepared and evaluated. The examples below illustrate the observed and measured effects of incorporating various permittivity lowering additives into extruded thermoplastic films that simulate magnet wire insulation. Each of the samples was prepared by incorporating a suitable additive into a PEEK polymeric material. Powders from PEEK resin material with different additives were compression molded into polymer films with PEEK as a base polymeric material. Each prepared film had a thickness of approximately 120 microns. Following preparation of the films, relative permittivity εᵣ of each sample was measured in a lab under ambient conditions. Permittivity was calculated utilizing Equation 1 as set forth above.

TABLE 4
Lowering Permittivity Using Different Additives
of polycyclic aromatic hydrocarbon (PAH) for PEEK

| Film Sample | Permittivity (k) |
|---|---|
| PEEK Control | 3.53 |
| PEEK + 15.0% by weight of DBT | 3.41 |
| PEEK + 20.0% by weight of Therminol 75 | 3.30 |
| PEEK + 15.0% by weight of Therminol 66 | 3.29 |
| PEEK + 58.0% by weight of Therminol 66 | 3.15 |

As shown in Table 4, the addition of each of the additives resulted in reduced permittivity. Therminol 66 (“HTP”) appeared to have the best performance and result in the greatest reduction in permittivity. It can be concluded that the permittivity of thermoplastic magnet wire insulation may be reduced as a result of utilizing PAH permittivity lowering additives (e.g., polyphenyls, polybenzyls, etc, and/or their fully or partially hydrogenated compounds. Additionally, the use of higher weight percentages of additives may generally result in lower permittivity.

Conditional language, such as, among others, “can,” “could,” “might,” or “may,” unless specifically stated otherwise, or otherwise understood within the context as used, is generally intended to convey that certain embodiments could include, while other embodiments do not include, certain features, elements, and/or operations. Thus, such conditional language is not generally intended to imply that features, elements, and/or operations are in any way required for one or more embodiments or that one or more embodiments necessarily include logic for deciding, with or without user input or prompting, whether these features, elements, and/or operations are included or are to be performed in any particular embodiment.

Many modifications and other embodiments of the disclosure set forth herein will be apparent having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A magnet wire comprising:
a conductor; and
at least one insulation layer formed around the conductor, the insulation layer comprising:
a base polymeric material; and
one or more additives incorporated into the base polymeric material, the one or more additives comprising at least one of (i) a polycyclic aromatic hydrocarbon or (ii) a partially or fully hydrogenated compound of a polycyclic aromatic hydrocarbon,
wherein the one or more additives lower the permittivity of the insulation layer relative to a control insulation layer formed solely from the base polymeric material.

2. The magnet wire of claim 1, wherein the one or more additives comprise at least one polyphenyl.

3. The magnet wire of claim 1, wherein the one or more additives comprise at least one polybenzyl.

4. The magnet wire of claim 1, wherein the one or more additives comprise at least one of (i) dibenzyltoluene, (ii) hydrogenated terphenyl, (iii) terphenyl or (iv) quaterphenyl.

5. The magnet wire of claim 1, wherein the one or more additives comprise at least one additive having a boiling point at standard atmospheric pressure of at least 250° C.

6. The magnet wire of claim 1, wherein the one or more additives comprise between 1.0% and 60.0% by weight of an insulation material used to form the insulation layer.

7. The magnet wire of claim 1, wherein the base polymeric material comprises a thermosetting material.

8. The magnet wire of claim 7, wherein the thermosetting material comprises at least one of (i) polyimide, (ii) polyamideimide, (iii) polyesterimide, (iv) polyamide-ester-imide, (v) polyetherimide. (vi) polybenzimidazole, or (vii) poly(benzimidazole-imide).

9. The magnet wire of claim 1, wherein the base polymeric material comprises a thermoplastic material.

10. The magnet wire of claim 9, wherein the thermoplastic material comprises one of (i) polyetheretherketone, (ii) polyaryletherketone, (iii) polyetherketoneketone, (iv) polyphenylsulfone, (v) polyethersulfone, (vi) poly(imide-sulfone), (vi) aromatic polyamide, or (vii) polyphenylene sulfide.

11. The magnet wire of claim 1, wherein a first permittivity of the insulation layer is at least 0.3 lower than a second permittivity of the control insulation layer.

12. The magnet wire of claim 1, wherein a first partial discharge inception voltage of the insulation layer is at least 5.0% higher than a second partial discharge inception voltage of the control insulation layer.

13. A magnet wire comprising:
a conductor; and
at least one insulation layer formed around the conductor, the insulation layer comprising:
a base thermosetting polymeric material; and
one or more additives incorporated into the base polymeric material, the one or more additives comprising at least one of (i) a polycyclic aromatic hydrocarbon or (ii) a partially or fully hydrogenated compound of a polycyclic aromatic hydrocarbon,
wherein the one or more additives lower the permittivity of the insulation layer relative to a control insulation layer formed solely from the base polymeric material.

14. The magnet wire of claim 13, wherein the one or more additives lower the permittivity of the insulation layer relative to a control insulation layer formed solely from the base thermosetting polymeric material.

15. The magnet wire of claim 13, wherein the one or more additives comprise at least one polyphenyl.

16. The magnet wire of claim 13, wherein the one or more additives comprise at least one polybenzyl.

17. The magnet wire of claim 13, wherein the one or more additives comprise at least one of (i) dibenzyltoluene, (ii) hydrogenated terphenyl, (iii) terphenyl or (iv) quaterphenyl.

18. The magnet wire of claim 13, wherein the one or more additives comprise between 1.0% and 60.0% by weight of an insulation material used to form the insulation layer.

19. The magnet wire of claim 13, wherein the base thermosetting polymeric material comprises at least one of (i) polyimide, (ii) polyamideimide, (iii) polyesterimide, (iv) polyamide-ester-imide, (v) polyetherimide. (vi) polybenzimidazole, or (vii) poly(benzimidazole-imide).

20. The magnet wire of claim 1, wherein a first permittivity of the insulation layer is at least 0.3 lower than a second permittivity of the control insulation layer.
